(19) United States
(12) Patent Application Publication
(10) Pub. No.: US 2006/0202867 A1
(43) Pub. Date: Sep. 14, 2006

(54) Keypad Identification Circuit and Method and Apparatus for Driving Different Types of Keypad Circuits

(76) Inventor: Kuan-Hong Hsieh, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/307,220

(22) Filed: Jan. 27, 2006

(30) Foreign Application Priority Data
Feb. 4, 2005 (TW) 094103801

(51) Int. Cl. H03M 11/00; H03K 17/94

(52) U.S. Cl. 341/22

(57) ABSTRACT

A keypad identification circuit connects with a keypad circuit (30) and includes a chip (20), which has been configured with a controller (201) and a memory (202), and an identification code generator (10). The identification code generator generates an identification code for the keypad circuit to the controller. The controller recognizes the identification code by use of an identification code table (2011) contained therein, and searches a corresponding exclusive driver (2022) together with a common driver (2021) from the memory to drive the installed keypad circuit. A related method and apparatus are also provided.

### TECHNICAL FIELD

The present invention relates to a keypad identification circuit and method and an apparatus, which can drive different types of keypad circuits.

### DESCRIPTION OF THE RELATED ART

Keypads (keyboards) are widely used in many appliances, such as computers and electronic cash registers. Keypads receive input from users and transfer the input to drivers for recognition. Nowadays, there are many types and brands of keypads.

Keypads, as well as other computer-related devices, are generally mass produced by original equipment manufacturers (OEMs) or by original design manufacturers (ODMs). A factory may produce many types of keypads for different client companies. To distinguish products for different client companies, additional hardware or software is usually needed to suit the requirements of different client companies. This can cause problems for the OEMs or ODMs.

Therefore, there is a need for an apparatus combined with a keypad identification circuit, which can differentiate and drive different types of keypads, thus eliminating the need for additional hardware or software individualized for the respective different client companies.

### SUMMARY

A keypad identification circuit used to recognize a plurality of types of keypad circuits and select a corresponding exclusive driver for each type based on that recognition is provided. The keypad identification circuit includes an identification code generator generating an identification code for each type of keypad circuit; and a controller connecting with a memory that stores a plurality of exclusive drivers. Wherein, the controller receives the identification code for one of the types of keypad circuits from the identification code generator, and selects an exclusive driver from the memory according to the identification code for the keypad circuit.

A method for identifying a type of an installed keypad circuit is also provided. The method comprises the steps of: a) generating an identification code for the installed keypad circuit; and b) identifying the identification code and selecting an exclusive driver according to the identification code to drive the installed keypad circuit. Step a) further includes: a1) setting a code defining circuit in a state that corresponds to the type of the keypad circuit; a2) controlling a first switching circuit to conduct; and a3) generating the identification code by the code defining circuit.

An apparatus for driving different types of keypad circuits is also provided. The apparatus comprises: a memory storing a plurality of exclusive drivers, each exclusive driver being used to drive a respective type of keypad circuit; and a controller having an identification code table, the identification code table containing information on each type of keypad circuit, the information identifies a corresponding exclusive driver to drive each type of keypad circuit. The controller receives an identification code from an identification code generator, recognizes an installed keypad circuit by use of the identification code table and selects a corresponding exclusive driver to drive the installed keypad circuit.

Other advantages and novel features will be drawn from the following detailed description with reference to the attached drawings, in which:

### BRIEF DESCRIPTION OF THE DRAWINGS

FIG. 1 is a block diagram of a keypad identification circuit according to an exemplary embodiment of the present invention together with a keypad circuit, the keypad identification circuit including an identification code generator;

FIG. 2 is a block diagram of a keypad identification circuit according to an alternative exemplary embodiment of the present invention, together with a keypad circuit;

FIG. 3 is similar to FIG. 1, but showing a circuit diagram for the identification code generator; and

FIG. 4 is a flowchart of a preferred method for identifying a particular type of keypad circuit and selecting a corresponding exclusive driver for the type of keypad circuit identified.

### DETAILED DESCRIPTION OF THE PREFERRED EMBODIMENTS

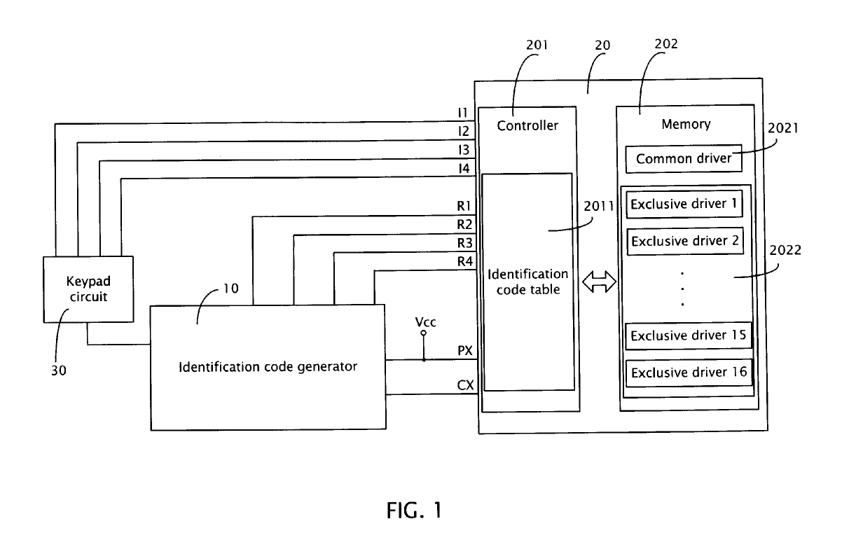

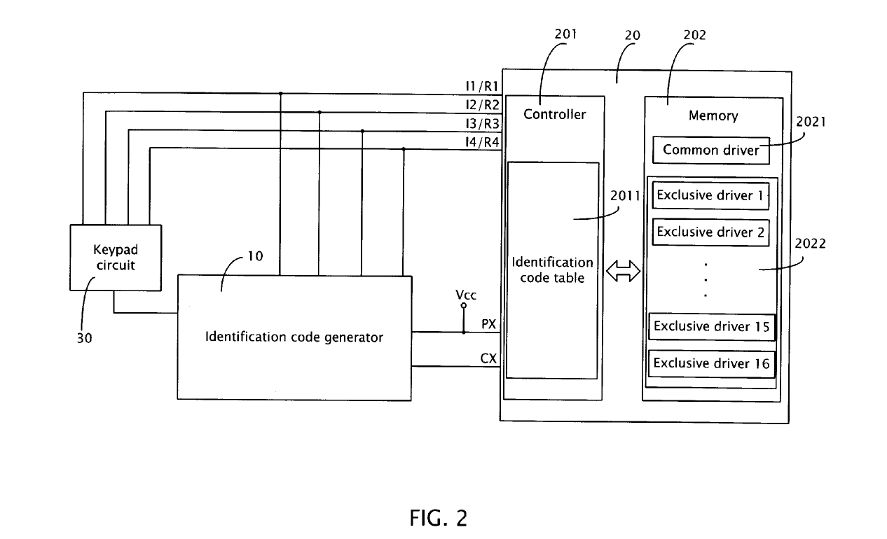

Referring to FIGS. 1 and 2, these are block diagrams of keypad identification circuits in accordance with exemplary embodiments of the present invention, together with corresponding keypad circuits. The keypad identification circuit connects with a keypad circuit 30, and includes a controlling apparatus (in these embodiments, a chip 20 with a memory 202 is used), and an identification code generator 10. The keypad circuit 30, the chip 20 and the identification code generator 10 interconnect through conducting lines (not labeled). The chip 20 possesses a plurality of pins, as shown in FIG. 1, including key signal input pins I1 through I4 which receive key signals from the keypad circuit 30, identification code input pins R1 through R4 which cooperate to read an identification code of the keypad circuit 30 from the identification code generator 10, a power pin PX which receives power for the chip 20 from an external power source Vcc, and a control pin CX which transfers control signals produced by the chip 20 to, for example, the identification code generator 10. In the alternative exemplary embodiment as shown in FIG. 2, the chip 20 is provided with pins I1/R1 through I4/R4 that have the functions of receiving both the key signals from the keypad circuit 30 and the identification code from the identification code generator 10. In FIG. 1, only four key signal input pins (I1, I2, I3 and I4), and four identification code input pins (R1, R2, R3 and R4) are shown, and in FIG. 2, only four key signal/identification code input pins (I1/R1, I2/R2, I3/R3, and I4/R4) are shown. However, it should be noted that any number of key signal input pins, any number of identification code input pins, and any number of key signal/identification code input pins are feasible. The number of key signal input pins and identification code input pins partly depends on the number and types of applicable keypad circuits.

The chip 20 is configured with a controller 201 and the memory 202 (in other embodiments, the memory 202 may be provided outside of the chip 20). The memory 202 stores a plurality of drivers for different types of keypad circuits, including a common driver 2021 and two or more exclusive drivers 2022. In FIGS. 1 and 2, a total of sixteen exclusive drivers 2022 are provided, but only exclusive drivers 1, 2, 15, and 16 are actually shown. The number of exclusive drivers 2022 corresponds to how many different types of keypad circuits may be driven by the chip 20, and corresponds to how many identification code input pins (or key signal/identification code input pins) must be provided to enable the chip 20 to drive all the different types of keypad circuits. In the example shown in FIGS. 1 and 2, the chip 20 can be used to drive sixteen different types of keypad circuits. Accordingly, the chip 20 must possess at least four identification code input pins R1 through R4 or four key signal/identification code input pins I1/R1 through I4/R4.

The controller 201 includes an identification code table 2011, which contains information on each type of keypad circuit and a corresponding identification code of each type of keypad circuit. The information also identifies a corresponding exclusive driver 2022 for each type of keypad circuit. The controller 201 receives an identification code from the identification code generator 10 via the identification code input pins R1 through R4 (or via the key signal/identification code input pins I1/R1 through I4/R4), recognizes the type of the installed keypad circuit 30 according to the identification code, and then selects a corresponding exclusive driver 2022 for the keypad circuit 30 as indicated by the identification code table 2011.

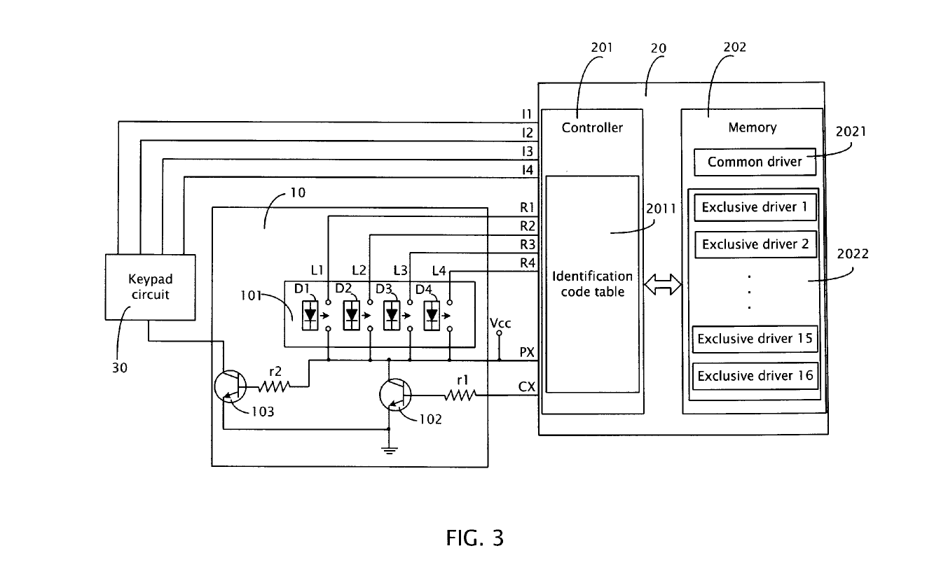

Referring to FIG. 3, the identification code generator 10 includes first and second switching circuits 102, 103, and a code defining circuit 101. The first switching circuit 102 is provided between the code defining circuit 101 and a reference voltage terminal (shown as ground), and is used to control the generation of the identification codes. The first switching circuit 102 switches on under the control of a controlling apparatus, such as the controller 201 by use of control signals via the control pin CX, and thus causes the code defining circuit 101 to generate an identification code for indicating the type of installed keypad circuit 30. The second switching circuit 103 is provided between the keypad circuit 30 and the reference voltage terminal, and is used to control the input of the key signals. In the present embodiments, the second switching circuit 103 is switched on while the first switching circuit 102 is switched off, and the second switching circuit 103 switches off when the first switching circuit 102 is switched on when power is supplied.

The first and second switching circuits 102, 103 in FIG. 3 are embodied as NPN (negative-positive-negative) transistors 102 and 103 as examples. The transistor 103 has its base connected with the external source Vcc and a plurality of terminals of the code defining circuit 101 via a resistor r2, its collector connected with the keypad circuit 30, and its emitter grounded. The transistor 102 has its base connected with the control pin CX of the chip 20 via a resistor r1, its collector connected with the external source Vcc and the plurality of terminals of the code defining circuit 101, and its emitter grounded. The code defining circuit 101 includes n (where n is a natural number) signal lines, each of which is pre-configured to be in one of two different states, i.e. an open circuit state, or a closed circuit state. Thus, by changing the n signal lines between the two states, 2ⁿ different combinations are possible, each corresponding to a particular identification code and a particular exclusive driver 2022. In FIG. 3, the code defining circuit 101 is shown including four signal lines L1, L2, L3, and L4, among which 2⁴=16 combinations can be produced corresponding to the 16 exclusive drivers 2022. The signal lines L1 through L4 are connected between the corresponding identification code input pins R1 through R4 and the collector of the transistor 102 respectively. Each of the signal lines L1 through L4 is pre-configured to be either in an open circuit state or in a closed circuit state. The signals lines L1 through L4 may be closed by the inclusion in-line of unidirectional conduction components, such as diodes D1, D2, D3, and D4 as shown in FIG. 3. When one of the signal lines is in an open state, the corresponding input pin is held at a high-level voltage. The pre-configuration chosen for the signal lines L1 through L4 controls the input pins R1 through R4 (or the key signal/identification code input pins I1/R1 through I4/R4) to be at different voltages. That is, each of the input pins R1 through R4 is at a high-level voltage or at a low-level voltage. Thereby sixteen different identification codes may be produced, each of which corresponds to a respective exclusive driver 2022.

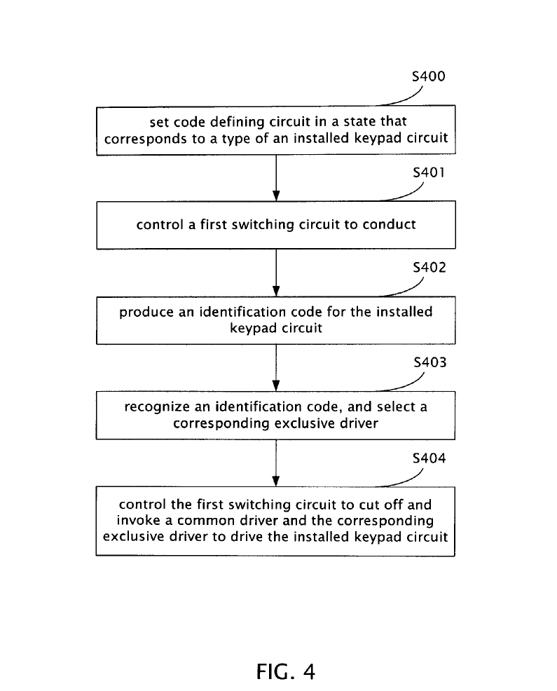

Referring to FIG. 4, this is a flowchart of a preferred method for identifying a particular type of keypad circuit and selecting a corresponding exclusive driver 2022 for the type of keypad circuit identified. In the following description, the installed keypad circuit 30 is used as an example. The method can be mainly generalized as follows: a) the identification code generator 10 generates an identification code for the installed keypad circuit 30; and b) a controlling apparatus such as the controller 201 recognizes the identification code, and selects a corresponding exclusive driver 2022 together with the common driver 2021 in order to drive the installed keypad circuit 30.

The method can be further detailed as follows. First, in step S400, the code defining circuit 101 is set in a particular state that corresponds to the type of the installed keypad circuit 30. That is, each of the signal lines L1, L2, L3, and L4 is set in a corresponding state, e.g., an open circuit state or a conducting (closed) circuit state, in order to produce an identification code that corresponds to the type of the installed keypad circuit 30 when the transistor 103 conducts. In step S401, the first switching circuit 102 is controlled to conduct by a controlling apparatus. In this embodiment, the controlling apparatus is the controller 201. The controller 201 sets the control pin CX and the identification code input pins R1, R2, R3 and R4 (or key signal/identification code input pins I1/R1, I2/R2, I3/R3, and I4/R4) at high-level voltages. Consequently, the first switching circuit 102 conducts and the second switching circuit 103 cuts off. The keypad circuit 30 is then prevented from operating. In step S402, each of the identification code input pins R1, R2, R3 and R4 (or key signal/identification code input pins I1/R1, I2/R2, I3/R3, and I4/R4) is either kept at the high-level voltage or changed to the low-level voltage according to whether the signal line connected therewith is open or conducting, and thereby the identification code for the installed keypad circuit 30 is produced. In step S403, the controller 201 recognizes the identification code represented by the voltage levels of the identification code input pins R1, R2, R3 and R4 (or the key signal/identification code input pins I1/R1, I2/R2, I3/R3, and I4/R4), and selects a corresponding exclusive driver 2022 from the memory 202 according to the identification code table 2011. In step S404, the controller 201 sets the control pin CX at a low-level voltage, to control the first switching circuit 102 to cut off and the second switching circuit 103 to conduct. The keypad circuit 30 is then enabled. Then the controller 201 invokes the common driver 2021 and the corresponding exclusive driver 2022 from the memory 202 to drive the keypad circuit 30.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A keypad identification circuit for identifying a plurality of different types of keypad circuits and selecting a corresponding exclusive driver for each type of keypad circuit based on the identification of each type of keypad circuit, comprising:
an identification code generator for generating an identification code for each type of keypad circuit; and
a controller connected with a memory that stores a plurality of exclusive drivers;
wherein, the controller receives the identification code for one of the types of keypad circuits from the identification code generator, and selects a corresponding exclusive driver from the memory according to the identification code for the keypad circuit.

2. The keypad identification circuit as claimed in claim 1, wherein the controller comprises an identification code table containing information on each type of keypad circuit, the information identifying a corresponding exclusive driver for each type of keypad circuit.

3. The keypad identification circuit as claimed in claim 1, wherein the controller is provided on an controlling apparatus, the apparatus comprising a plurality of key signal input pins and a plurality of identification code input pins, the key signal input pins being used to receive key signals from an installed keypad circuit connected with the apparatus, and the identification code input pins being used to receive an identification code of the installed keypad circuit from the identification code generator.

4. The keypad identification circuit as claimed in claim 3, wherein the apparatus further comprises a control pin for controlling the identification code generator.

5. The keypad identification circuit as claimed in claim 4, wherein the apparatus further comprises a power pin for receiving power for the apparatus from a power source.

6. The keypad identification circuit as claimed in claim 4, wherein the identification code generator further comprises a first switching circuit and a code defining circuit, the first switching circuit being provided between the code defining circuit and a reference voltage terminal and being controlled by the apparatus, the code defining circuit comprising a plurality of signal lines connected between the corresponding identification code input pins and the first switching circuit, each of the signal lines being configured in an open circuit state or in a closed circuit state according to the type of the installed keypad circuit.

7. The keypad identification circuit as claimed in claim 6, wherein when any one of the signal lines is configured in a closed circuit state, the signal line includes in-line a unidirectional conduction component.

8. The keypad identification circuit as claimed in claim 6, wherein the first switching circuit is controlled by the apparatus to conduct so as to generate an identification code corresponding to the installed keypad circuit to the controller via the code defining circuit.

9. The keypad identification circuit as claimed in claim 6, wherein the identification code generator further comprises a second switching circuit provided between the installed keypad circuit and the reference voltage terminal.

10. The keypad identification circuit as claimed in claim 10, wherein the second switching circuit is controlled to be switched off when the first switching circuit conducts, and to be switched on when the first switching circuit cuts off.

11. The keypad identification circuit as claimed in claim 6, wherein the reference voltage terminal is ground.

12. A method for identifying a type of an installed keypad circuit, comprising the steps of:
generating an identification code for the installed keypad circuit; and
identifying the identification code, and selecting an exclusive driver according to the identification code to drive the installed keypad circuit.

13. The method for identifying a type of an installed keypad circuit as claimed in claim 12, wherein the step of generating an identification code further comprises:
setting a code defining circuit in a state that corresponds to the type of the installed keypad circuit;
controlling a first switching circuit to conduct; and
generating of the identification code by the code defining circuit.

14. The method for identifying a type of keypad circuit as claimed in claim 12, wherein the step of identifying the identification code is implemented by a controller.

15. The method for identifying a type of keypad circuit as claimed in claim 14, wherein the code defining circuit comprises a plurality of signal lines provided between the controller and the first switching circuit.

16. The method for identifying a type of keypad circuit as claimed in claim 15, wherein setting a code defining circuit in a state that corresponds to a type of the installed keypad circuit comprises setting each of the signal lines in an open circuit state or in a closed circuit state.

17. The method for identifying a type of keypad circuit as claimed in claim 15, wherein the identification code is generated by the conduction of the first switching circuit.

18. An apparatus for driving different types of keypad circuits, comprising: a memory storing a plurality of exclusive drivers, each exclusive driver being used to drive a respective type of keypad circuit; and
a controller comprising an identification code table, the identification code table containing information on each type of keypad circuit, the information identifying a corresponding exclusive driver to drive each type of keypad circuit;
wherein the controller receives an identification code from an identification code generator, recognizes an installed keypad circuit by use of the identification code table, and selects a corresponding exclusive driver to drive the installed keypad circuit.

19. The apparatus for driving different types of keypad circuits as claimed in claim 18, wherein the installed keypad circuit connected with the apparatus, the apparatus is provided with a plurality of key signal input pins and a plurality of identification code input pins, the key signal input pins are used to receive key signals from the installed keypad circuit, and the identification code input pins are used to receive the identification code of the installed keypad circuit from the identification code generator.
